(19) United States
(12) Patent Application Publication
(10) Pub. No.: US 2020/0044139 A1
(43) Pub. Date: Feb. 6, 2020

(54) PIEZOELECTRIC TRANSFORMER AND ELECTRONIC APPARATUS INCLUDING PIEZOELECTRIC TRANSFORMER

(71) Applicant: CANON KABUSHIKI KAISHA, Tokyo (JP)

(72) Inventors: Miki Ueda, Tokyo (JP); Takanori Matsuda, Chofu-shi (JP); Makoto Kubota, Yokohama-shi (JP); Akira Uebayashi, Tokyo (JP); Norihiro Suzuki, Yokohama-shi (JP)

(21) Appl. No.: 16/525,093

(22) Filed: Jul. 29, 2019

(30) Foreign Application Priority Data
Aug. 2, 2018 (JP) 2018-145860

(51) Int. Cl. H01L 41/107; H01L 41/04; H01L 41/053

(52) U.S. Cl. CPC H01L 41/107; H01L 41/0536; H01L 41/044

(57) ABSTRACT

There is provided a piezoelectric transformer including a first output terminal, a first piezoelectric element connected to the first output terminal, a second output terminal, a second piezoelectric element connected to the second output terminal, an input terminal, and a third piezoelectric element connected to the input terminal, wherein each of the first and second output terminals is formed to be individually connectable to a corresponding external load and outputs a voltage at a different frequency.

### BACKGROUND

### Field of the Disclosure

The present disclosure generally relates to a piezoelectric element and more specifically to a piezoelectric element with a low vibration loss, which is achieved through control of the support position of the element. The present disclosure also relates to a piezoelectric transformer, a piezoelectric transformer apparatus, and an electronic apparatus that includes the piezoelectric element.

### Description of the Related Art

Piezoelectric transformers have been available as an electronic component that performs voltage conversion in an electronic apparatus to raise or drop a voltage. For example, Japanese Patent Application Laid-Open No. 51-123592 discusses a piezoelectric transformer (a rod-like complex piezoelectric transformer), which is configured to have two pairs of piezoelectric ceramic parts being sandwiched by metal cylinders. These piezoelectric ceramic parts are arranged in such a manner that electrodes of the same polarity face each other.

One of the two pairs of piezoelectric ceramic parts of this rod-like complex piezoelectric transformer is used as an input unit, and the other pair is used as an output unit. If electrical energy in the form of an alternating voltage is applied to the piezoelectric ceramic parts used as the input unit, vibration is excited by the inverse piezoelectric effect in the piezoelectric ceramic parts used as the input unit. The electrical energy is converted into elastic energy. This vibration causes elastic deformation of the piezoelectric ceramic part, and the positive piezoelectric effect of the piezoelectric ceramic parts used as the output unit generates electromotive force. In other words, the elastic energy is converted back into electrical energy and is output from the output unit. With this configuration, a voltage is applied to the input unit, and a voltage generated at the output unit is obtained via mechanical vibration.

### SUMMARY

Typical rod-like complex piezoelectric transformers are generally designed to correspond to a certain resonance frequency, and therefore, substantially a single value is used as a drive frequency. Thus, when one wishes to change the input signals of frequencies of several different alternating voltages, piezoelectric transformers corresponding to a desired number of frequencies are needed, resulting in an increase in size of an apparatus.

According to an aspect of the present disclosure, there is provided a piezoelectric transformer including a first output terminal, a first piezoelectric element connected to the first output terminal, a second output terminal, a second piezoelectric element connected to the second output terminal, an input terminal, and a third piezoelectric element connected to the input terminal, wherein each of the first and second output terminals is formed to be individually connectable to a corresponding external load and outputs a voltage at a different frequency.

By arranging a plurality of output units that correspond to different drive frequencies, a piezoelectric transformer that can output different power levels can be provided. Consequently, downsizing and higher integration of the apparatus can be achieved.

Further features of the present disclosure will become apparent from the following description of exemplary embodiments with reference to the attached drawings.

### BRIEF DESCRIPTION OF THE DRAWINGS

FIG. 1 schematically illustrates a conventional piezoelectric transformer.

FIG. 2 schematically illustrates displacement amount distributions and stress distributions at the time of stretching vibration (first to fourth orders) when a structure undergoes mechanical resonance.

FIG. 3 schematically illustrates piezoelectric transformers according to exemplary embodiments of the present disclosure.

FIGS. 4A to 4D schematically illustrate side views of piezoelectric transformers according to exemplary embodiments of the present disclosure.

FIGS. 5A and 5B each schematically illustrate a relationship between input and output units and a displacement amount at the time of stretching vibration of a piezoelectric transformer according to an exemplary embodiment of the present disclosure.

FIGS. 6A and 6B each illustrate a relationship between a drive frequency and a step-up ratio according to an exemplary embodiment of the present disclosure.

FIG. 7 schematically illustrates piezoelectric transformers according to exemplary embodiments of the present disclosure.

### DESCRIPTION OF THE EMBODIMENTS

Hereinafter, exemplary embodiments of the present disclosure will be described.

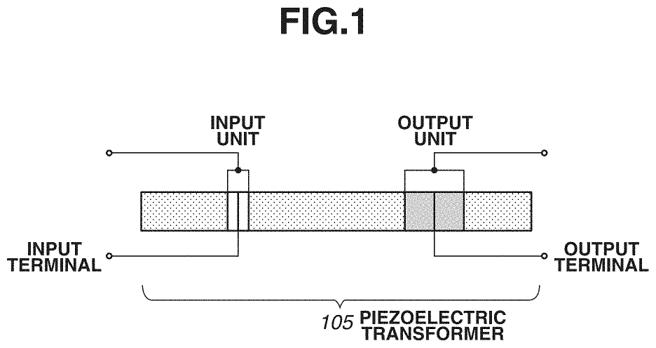

FIG. 1 schematically illustrates a conventional piezoelectric transformer, which has a configuration with two pairs of piezoelectric ceramic parts being sandwiched by metal cylinders, where these piezoelectric ceramic parts are arranged in such a manner that electrodes of the same polarity face each other. Namely, a voltage is applied to an input unit, and a voltage generating at an output unit is obtained via mechanical vibration. Such a piezoelectric transformer is designed to correspond to a certain resonance frequency, not to receive a plurality of different drive frequencies.

To solve the above issue, piezoelectric transformers and electronic apparatuses including the piezoelectric transformer according to exemplary embodiments of the present disclosure will be described.

### (Configuration of Piezoelectric Element and Piezoelectric Transformer)

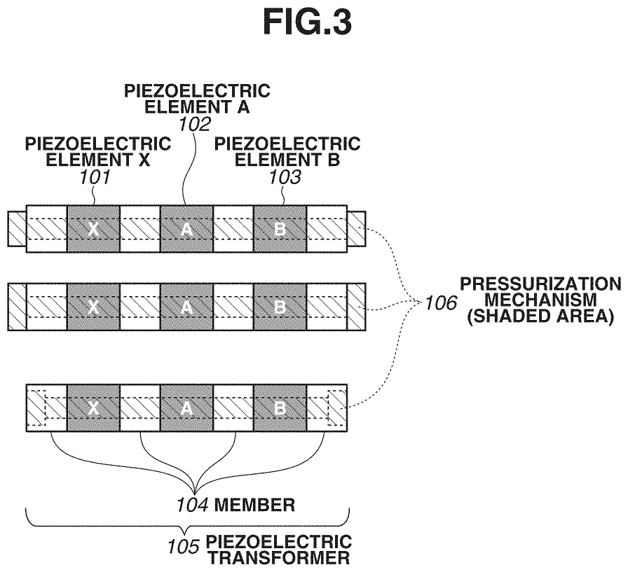

FIG. 3 schematically illustrates piezoelectric transformers according to exemplary embodiments of the present disclosure. Any of these piezoelectric transformers may have a cylindrical shape, for example. More specifically, any of these piezoelectric transformers may have a cylindrical shape having an outside diameter R. In the center of this cylindrical shape, a hole may be provided into which a bolt having an inside diameter r is inserted. Tightening the piezoelectric transformer with a nut from either end of the structure improves destruction resistance to tension stress on the piezoelectric transformer, thus enabling the piezoelectric transformer to be used with higher power. As the pressurization means, as schematically illustrated in FIG. 3, tightening the piezoelectric transformer with a bolt, a nut, or the like is also desirable by using a through hole provided in the center of the piezoelectric transformer. In this case, it is desirable that the in-plane uniformity of the stress on the piezoelectric elements at the time of stretching vibration, used when the piezoelectric transformer is driven, be maintained as high as possible. It is also desirable that high output efficiency be ensured and the durability be improved. The following configuration may be adopted to achieve these ends. Namely, the head of a bolt or a nut is embedded into the pressurization mechanism used for the tightening. Alternatively, the cross-sectional shape of the head of a bolt or a nut may be equal to that of the piezoelectric transformer.

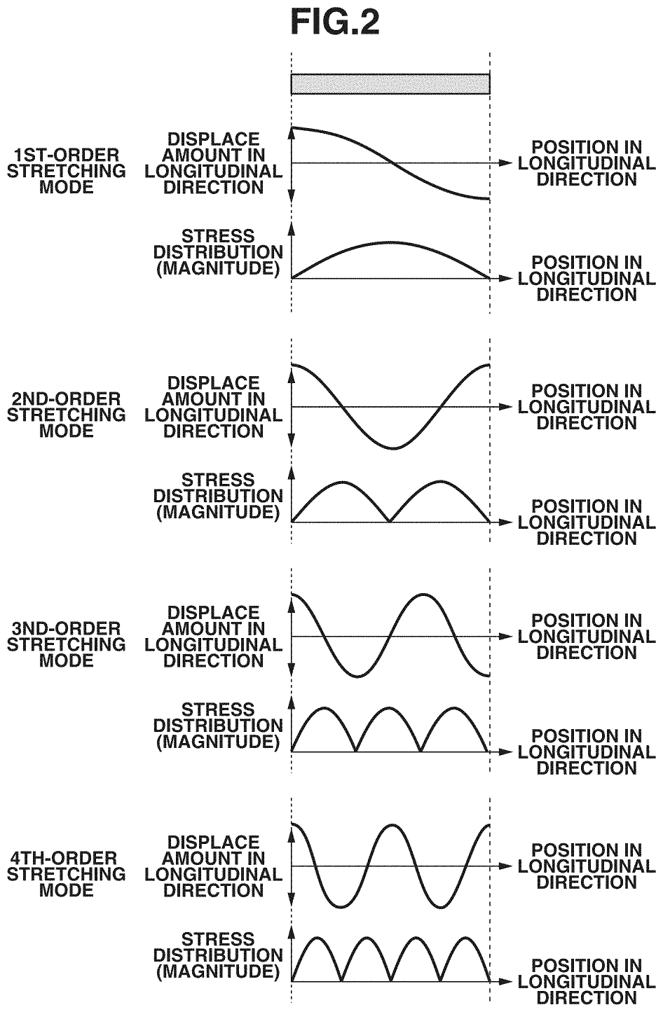

Stretching resonance is used for driving the piezoelectric transformer. FIG. 2 schematically illustrates displacement amount and stress distributions at the time of first- to fourth-order stretching resonance. By arranging the input unit and the output unit at positions where the stress is maximized at the time of stretching resonance used for driving the piezoelectric elements, high output efficiency can be obtained.

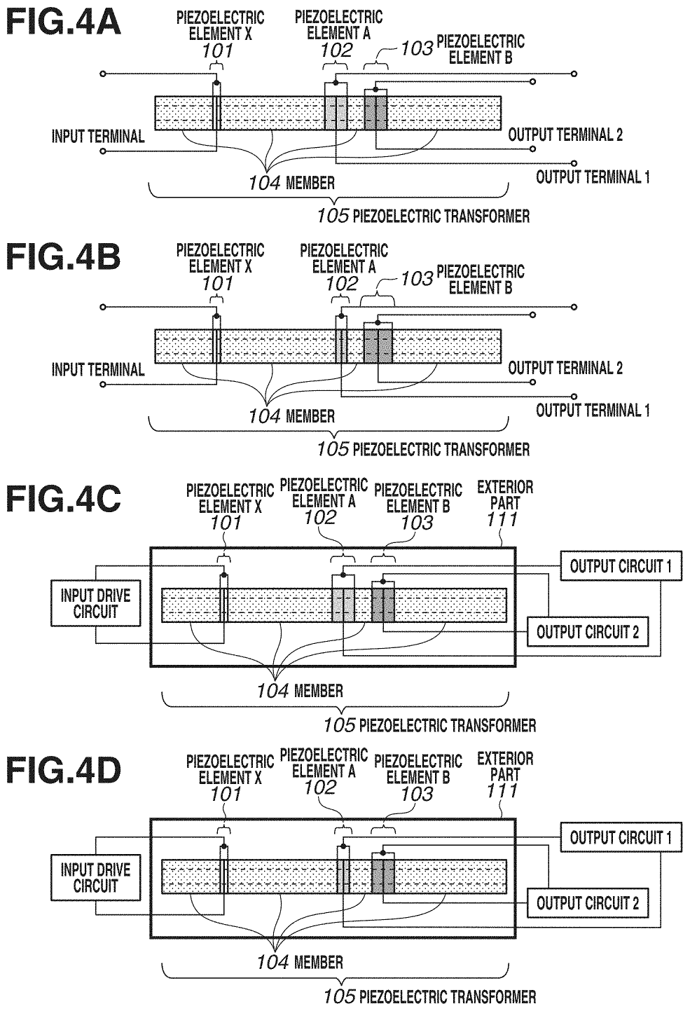

To estimate the output voltage of the piezoelectric transformer, finite element method package software “ANSYS®” (ANSYS Inc.) was used. Regarding the material properties used for simulations, physical properties of commercially available lead zirconate titanate material for the piezoelectric ceramic parts and physical properties of commercially available stainless steel (SUS) for the metal parts were used. FIGS. 4A and 4B illustrate exemplary embodiments of piezoelectric transformers, each of which has a length L, an outside diameter R, and an inside diameter r (indicated by dotted lines). Each of the piezoelectric transformers is configured to have a cylindrical input unit (piezoelectric element X or third piezoelectric element), an output unit 1 (piezoelectric element A or first piezoelectric element), and an output unit 2 (piezoelectric element B or second first piezoelectric element) which are each sandwiched by the corresponding shaded metal cylinders among four shaded metal cylinders. Each of the piezoelectric elements X, A, and B has front and rear surfaces on which an electrode film (not illustrated) is formed and has two polarized piezoelectric ceramic parts arranged in such a manner that electrodes of the same polarity face each other.

A first exemplary embodiment of the present disclosure will be described below. A description will be provided of a piezoelectric transformer according to the first exemplary embodiment in which a member, an input unit (piezoelectric element X or third piezoelectric element), a member, an output unit 1 (piezoelectric element or first piezoelectric element), an output unit 2 (piezoelectric element B or second piezoelectric element), and a member are stacked in this order. The piezoelectric transformer illustrated in FIG. 4A has a length L of 360 mm, an outside diameter R of 40 mm, and an inside diameter r of 16 mm A length lin from an end of the structure to the center of the input unit (piezoelectric element X) is 63 mm, and a length lout1 from the end of the structure to the center of the output unit 1 (piezoelectric element A) is 183 mm. In addition, a length lout2 from the end of the structure to the center of the output unit 2 (piezoelectric element B) is 228.2 mm Each of the two piezoelectric ceramic parts that form the input unit has a thickness of 3 mm, and each of the two piezoelectric ceramic parts that form the output unit 1 (piezoelectric element A) has a thickness of 12 mm. Likewise, each of the two piezoelectric ceramic parts that form the output unit 2 (piezoelectric element B) has a thickness of 12 mm.

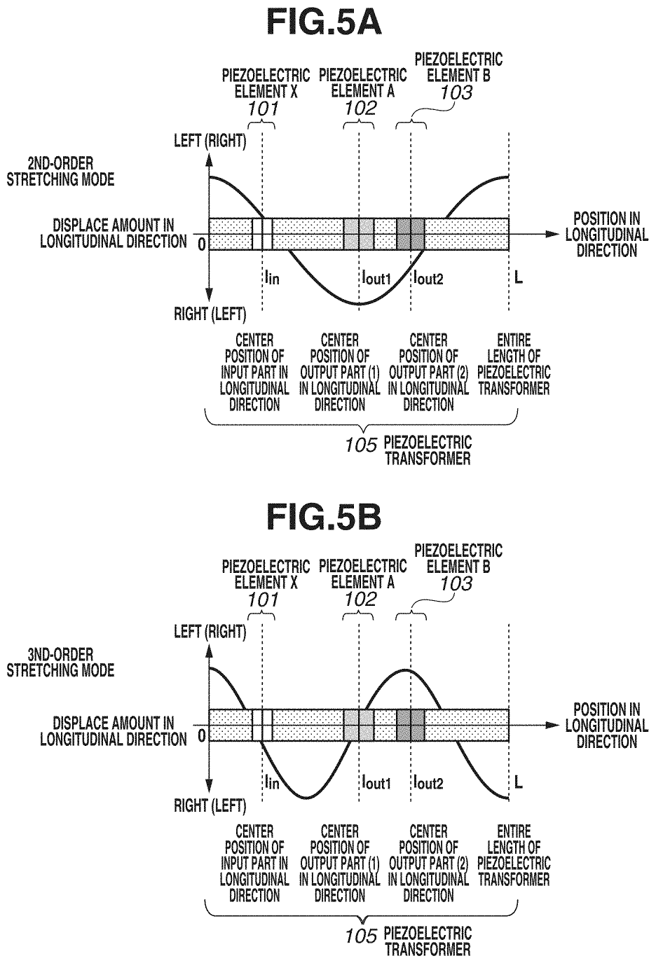

FIGS. 5A and 5B schematically illustrate relationships between displacement amounts at the time of second-order and third-order stretching vibration and the input unit (piezoelectric element X), the output unit 1 (piezoelectric element A), and the output unit 2 (piezoelectric element B) according to the present exemplary embodiment. FIGS. 5A and 5B illustrate relationships between the center positions of the input and output units and the displacement amounts at the time of second-order and third-order stretching vibration. In FIGS. 5A and 5B, the piezoelectric bodies of the output units and input unit (piezoelectric element X) are illustrated with the same thickness for simplicity, focusing on the center positions of the input and output units. Since the stress on the output unit 1 (piezoelectric element A) at the time of second-order stretching vibration decreases, the output unit 1 (piezoelectric element A) turns off. Thus, the output is obtained from the output unit 2 (piezoelectric element B).

With such a configuration, an alternating voltage Vin was applied to the input unit (piezoelectric element X), and voltages Vout1 and Vout2 outputted from the output unit 1 (piezoelectric element A) and the output unit 2 (piezoelectric element B), respectively, were estimated.

In addition, the ratios of the voltages (voltage transformation ratio), namely, Vout1/Vin and Vout2/Vin, were estimated.

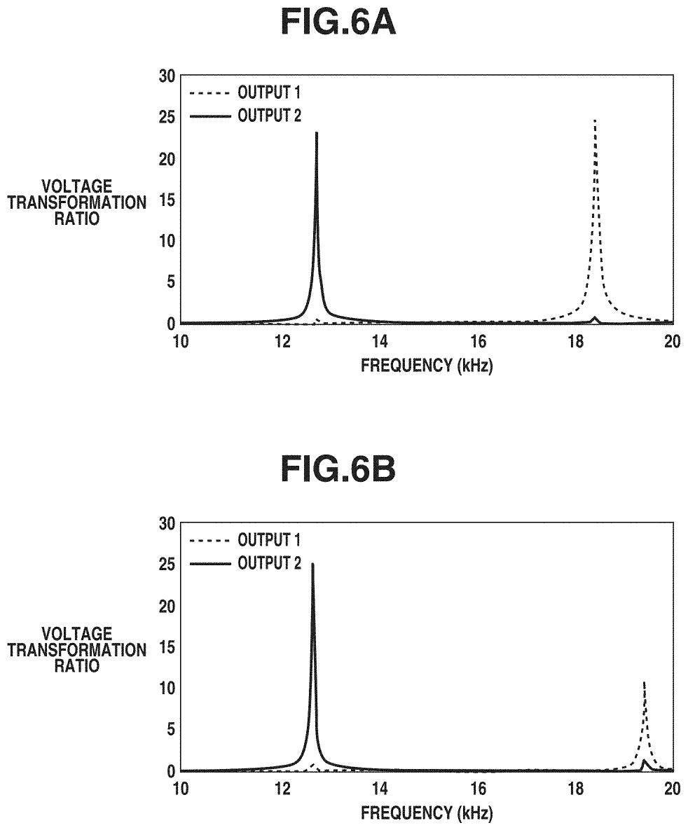

FIG. 6A illustrates a result thereof. The horizontal axis represents the frequency of the input voltage and the vertical axis represents the output voltage transformation ratio. While a large output was obtained from the output unit 2 (output 2 in FIG. 6A) from 12 kHz to 14 kHz, almost no output was obtained from the output unit 1 (output 1 in FIG. 6A). In contrast, while a large output was obtained from the output 1 from 18 kHz to 20 kHz, almost no output was obtained from the output 2. As seen from this result, the piezoelectric transformer according to the present exemplary embodiment outputs different converted voltages from its two respective output terminals by the drive frequency being changed.

The reasons for this are as follow. First, since the output unit 1 (piezoelectric element A) is located at an antinode of the resonance and the stress thereon decreases at the time of second-order stretching vibration, almost no output is obtained from the output unit 1 (piezoelectric element A). In addition, since the stress on the output unit 1 (piezoelectric element A) is maximized and the stress on the output unit 2 (piezoelectric element B) decreases at the time of third-order stretching vibration, while an output is obtained from the output unit 1 (piezoelectric element A), almost no output is obtained from the output unit 2 (piezoelectric element B).

According to the first exemplary embodiment, by applying input signals of two different frequencies, different outputs can be obtained from the output unit 1 (piezoelectric element A) and the output unit 2 (piezoelectric element B), respectively.

A second exemplary embodiment of the present disclosure will be described below. A piezoelectric transformer according to the present exemplary embodiment in which a member, an input unit (piezoelectric element X or third piezoelectric element), a member, an output unit 1 (piezoelectric element A or first piezoelectric element), an output unit 2 (piezoelectric element B or second piezoelectric element), and a member are stacked in this order will be described. The piezoelectric transformer illustrated in FIG. 4B has a length L of 360 mm, an outside diameter R of 40 mm, and an inside diameter r of 16 mm A length lin from an end of the structure to the center of the input unit (piezoelectric element X) is 63 mm, and a length lout1 from the end of the structure to the center of the output unit 1 (piezoelectric element A) is 189.5 mm. In addition, a length lout2 from the end of the structure to the center of the output unit 2 (piezoelectric element B) is 238.2 mm Each of the two piezoelectric ceramic parts that form the input unit (piezoelectric element X) has a thickness of 2 mm, and each of the two piezoelectric ceramic parts that form the output unit 1 (piezoelectric element A) has a thickness of 5 mm. In addition, each of the two piezoelectric ceramic parts that form the output unit 2 (piezoelectric element B) has a thickness of 15 mm.

FIGS. 5A and 5B schematically illustrate relationships between displacement amounts at the time of second-order and third-order stretching vibration and the input unit (piezoelectric element X), the output unit 1 (piezoelectric element A), and the output unit 2 (piezoelectric element B) according to the present exemplary embodiment. FIGS. 5A and 5B illustrate relationships between the center positions of the input and output units and the displacement amounts at the time of second-order and third-order stretching vibration. In FIGS. 5A and 5B, the piezoelectric bodies of the output units and input unit (piezoelectric element X) are illustrated with the same thickness for simplicity, focusing on the center positions of the input and output units. Since the stress on the output unit 1 (piezoelectric element A) at the time of second-order stretching vibration decreases, the output unit 1 (piezoelectric element A) turns off. Thus, the output is obtained from the output unit 2 (piezoelectric element B). In addition, according to the present exemplary embodiment, since the piezoelectric body of the output unit 1 (piezoelectric element A) and that of the output unit 2 (piezoelectric element B) greatly differ from each other, outputs can be obtained with greatly different voltage transformation ratios.

With such a configuration, an alternating voltage Vin was applied to the input unit (piezoelectric element X), and Vout1/Vin and Vout2/Vin, which are the ratios (voltage transformation ratio) regarding the voltages Vout1 and Vout2 output by the output unit 1 (piezoelectric element A) and the output unit 2 (piezoelectric element B), were estimated. FIG. 6B illustrates the result. The horizontal axis represents the frequency of the input voltage and the vertical axis represents the output voltage transformation ratio. Since the output unit 1 (piezoelectric element A) is located at an antinode of the resonance and the stress thereon decreases at the time of second-order stretching vibration, almost no output is obtained from the output unit 1 (piezoelectric element A). In addition, since the stress on the output unit 1 (piezoelectric element A) is maximized and the stress on the output unit 2 (piezoelectric element B) decreases at the time of third-order stretching vibration, while an output is obtained from the output unit 1 (piezoelectric element A), almost no output is obtained from the output unit 2 (piezoelectric element B). By using piezoelectric ceramic parts having different thicknesses as the output unit 1 (piezoelectric element A) and the output unit 2 (piezoelectric element B), outputs can be obtained from the output unit 1 (piezoelectric element A) and the output unit 2 at two different frequencies with different voltage transformation ratios.

According to the present exemplary embodiment, lead zirconate titanate material is used as the piezoelectric material, and SUS is used as the cylindrical metal material. However, even when different piezoelectric material and metal material are used, as long as the requirements of the present disclosure are satisfied, the advantageous effects of the present disclosure can be obtained. To obtain a large on-and-off ratio of the output per output terminal when a plurality of different drive frequencies are used, it is desirable that the output unit to be turned off is arranged at a position where the stress is minimized in the corresponding vibration mode. To improve the output efficiency, it is desirable that the output unit to be used is arranged at a position where the stress is maximized in the corresponding vibration mode.

Even if two or more input units are used, as long as the requirements of the present disclosure are satisfied, the advantageous effects of the present disclosure can be obtained.

Even if three or more output units are used, as long as the requirements of the present disclosure are satisfied, the advantageous effects of the present disclosure can be obtained. The piezoelectric elements A, B, and X may be unequally spaced from each other.

Even if the input unit and the output units have a shape in which piezoelectric ceramic parts and electrodes are stacked on each other, as long as the requirements of the present disclosure are satisfied, the advantageous effects of the present disclosure can be obtained.

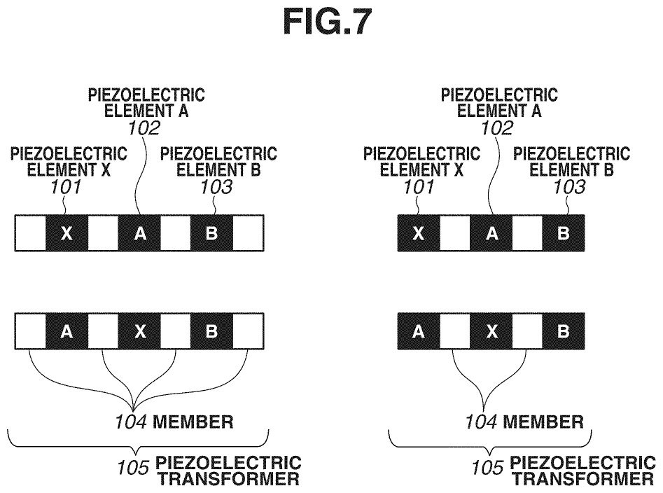

A piezoelectric transformer according to an exemplary embodiment includes a piezoelectric element A connected to a first output terminal, a second output terminal, a piezoelectric element B connected to the second output terminal, an input terminal, a piezoelectric element X connected to the input terminal, and members that sandwich the above members and that are represented as white rectangles in FIG. 7. As illustrated in FIG. 7, these members do not necessarily need to be stacked in the order as described in the above exemplary embodiments. For example, a piezoelectric body may be arranged at both ends of the piezoelectric transformer. For example, even when the pressurization mechanism, the length of the input unit, and the lengths of the output units are changed, as long as the requirements of the present disclosure are satisfied, the advantageous effects of the present disclosure can be obtained. In addition, the members represented as the white rectangles may be made of, not only metal, but also insulating material so that the piezoelectric element A and the piezoelectric element B are electrically insulated from each other.

### (Electronic Apparatus)

It is desirable that a piezoelectric transformer apparatus according to an exemplary embodiment of the present disclosure be provided with an exterior unit and be incorporated in an electronic apparatus, and that a piezoelectric transformer be connected to an input drive circuit and an output circuit (external load) and used. Since a plurality of output units that correspond to different drive frequencies are arranged and different power levels can be outputted, downsizing of the electronic apparatus can be achieved.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2018-145860, filed Aug. 2, 2018, which is herein incorporated by reference in its entirety.

What is claimed is:

1. A piezoelectric transformer comprising:
a first output terminal;
a first piezoelectric element connected to the first output terminal;
a second output terminal;
a second piezoelectric element connected to the second output terminal;
an input terminal; and
a third piezoelectric element connected to the input terminal,
wherein each of the first and second output terminals is formed to be individually connectable to a corresponding external load and outputs a voltage at a different frequency.

2. The piezoelectric transformer according to claim 1, wherein the first, second, and third piezoelectric elements are stacked in a linear direction, and a member is arranged between the first and second piezoelectric elements.

3. The piezoelectric transformer according to claim 2, wherein at least one of the first and second piezoelectric elements is adjacent to the member.

4. The piezoelectric transformer according to claim 1, further comprising a pressurization mechanism, wherein the pressurization mechanism causes the first, second, and third piezoelectric elements to be pressed together in a linear direction.

5. The piezoelectric transformer according to claim 1, wherein the third piezoelectric element is electrically insulated from the first and second piezoelectric elements.

6. The piezoelectric transformer according to claim 1, wherein the first, second, and third piezoelectric elements are unequally spaced from each other in a linear direction.

7. The piezoelectric transformer according to claim 4, wherein the pressurization mechanism includes a portion which extends through the piezoelectric transformer in the linear direction.

8. The piezoelectric transformer according to claim 4, wherein the pressurization mechanism is embedded into the piezoelectric transformer.

9. The piezoelectric transformer according to claim 1, wherein each of the first to third piezoelectric elements is formed by piezoelectric ceramic parts and electrodes being stacked on each other in a linear direction.

10. An electronic apparatus comprising:
the piezoelectric transformer according to claim 1; and
a drive circuit that supplies an alternating voltage.
